(19) United States
(12) Patent Application Publication
(10) Pub. No.: US 2026/0206326 A1
(43) Pub. Date: Jul. 16, 2026

(54) SEMICONDUCTOR DEVICE

(71) Applicant: Renesas Electronics Corporation, Tokyo (JP)

(72) Inventor: Yuji ISHII, Tokyo (JP)

(21) Appl. No.: 19/447,069

(22) Filed: Jan. 13, 2026

(30) Foreign Application Priority Data
Jan. 16, 2025 (JP) 2025-006153

(51) Int. Cl. H10D 89/60

(52) U.S. Cl. CPC H10D 89/611

(57) ABSTRACT

A semiconductor device including a Zener diode, includes: an n-type semiconductor substrate; a p-type well region; an n-type diffusion region; and a p-type impurity region. An impurity concentration of the p-type impurity region is higher than an impurity concentration of the p-type well region. The p-type impurity region surrounds at least a part of the n-type diffusion region in plan view. The p-type well region forms a quadrangular shape in plan view. Each corner of the p-type well region is exposed from the p-type impurity region in plan view. A cathode of the Zener diode includes the n-type diffusion region. An anode of the Zener diode includes the p-type well region and the p-type impurity region.

### CROSS-REFERENCE TO RELATED APPLICATIONS

The disclosure of Japanese Patent Application No. 2025-006153 filed on January 16, 2025, including the specification, drawings and abstract is incorporated herein by reference in its entirety.

### BACKGROUND

The present invention relates to a semiconductor device, particularly to a semiconductor device including a Zener diode.

A semiconductor device that integrates a power MOSFET (Metal Oxide Semiconductor Field Effect Transistor) and a control circuit for controlling the operation of the power MOSFET has been developed. Such a semiconductor device may also be referred to as an IPD (Intelligent Power Device).

There are disclosed techniques listed below.

[Patent Document 1] Japanese Unexamined Patent Application Publication No. 2015-88617

[Patent Document 2] Japanese Unexamined Patent Application Publication No. H6-310738

For example, Patent Document 1 discloses an IPD equipped with two power MOSFETs for output and a control circuit. The power MOSFET is a trench gate type MOSFET. The control circuit includes a plurality of circuits with various functions and a plurality of MOSFETs for configuring these circuits. For example, the control circuit includes a gate driver circuit, a charge pump circuit, a temperature detection circuit, a current detection circuit and a protection circuit, and also includes a plurality of planar type MOSFETs as a part of these circuits.

The protection circuit has a function for protecting the plurality of planar type MOSFETs from a surge voltage and the like. A Zener diode may be used as one of the protection circuit.

Patent Document 2 discloses a Zener diode including an n-type cathode region and a p-type anode region. The n-type cathode region is formed so as to surround the p-type anode region.

### SUMMARY

A semiconductor substrate of the IPD is comprised of an n-type support substrate and an n-type semiconductor layer formed on the n-type support substrate. The relatively high concentration support substrate forms a drain region, while the relatively low concentration semiconductor layer forms a drift region. The p-type anode region is formed so as to surround the n-type cathode region in order to electrically separate the n-type cathode region from the n-type semiconductor substrate. Since a drain electrode is formed on a lower surface of the semiconductor substrate, a high voltage is applied from the lower surface of the semiconductor substrate. The substrate breakdown voltage of the control circuit needs to be higher than the avalanche breakdown voltage of the power MOSFET.

On the other hand, in the recent IPDs, a method that thins the drift region and that increases the impurity concentration of the n-type drift region has been implemented to reduce the ON-resistance of the power MOSFET. Also, in the Zener diode, there is a demand to decrease the resistance of the anode and to increase amount of the current per unit area of the Zener diode in order to reduce the area of the Zener diode. To achieve this, a method of increasing the impurity concentration of the impurity region forming the anode can be considered.

For these reasons, it is difficult to ensure the substrate breakdown voltage of the control circuit containing the Zener diode. That is, it is difficult to ensure the breakdown voltage between the p-type anode region and the n-type drift region. Therefore, it is required to ensure the breakdown voltage between the p-type anode region and the n-type drift region by reducing the ON-resistance of the power MOSFET and by increasing amount of the current of the Zener diode. In other words, it is required to improve the performance of the semiconductor device and ensure the reliability of the semiconductor device.

Other problems and novel features will become apparent from the description of this specification and the accompanying drawings.

The typical ones of the embodiments disclosed in the present application will be briefly described as follows.

A semiconductor device according to one embodiment includes a Zener diode. The semiconductor device includes: a semiconductor substrate; a first impurity region formed in the semiconductor substrate and forming a quadrangular shape in plan view; a second impurity region formed in the first impurity region; and a third impurity region formed in the first impurity region and surrounding at least a part of the second impurity region in plan view. Here, a conductivity type of each of the semiconductor substrate and the second impurity region is an n-type, and a conductivity type of each of the first impurity region and the third impurity region is the p-type. An impurity concentration of the third impurity region is higher than an impurity concentration of the first impurity region. Each corner of the first impurity region is exposed from the third impurity region in plan view. A cathode of the Zener diode includes the second impurity region. Also, an anode of the Zener diode includes the first impurity region and the third impurity region.

According to one embodiment, the performance of the semiconductor device can be improved, and the reliability of the semiconductor device can be ensured.

### BRIEF DESCRIPTION OF THE DRAWINGS

FIG. 1 is a plan view showing a semiconductor device according to the first embodiment.

FIG. 2 is a cross-sectional view showing a semiconductor device according to the first embodiment.

FIG. 3 is a plan view showing a Zener diode according to the first embodiment.

FIG. 4 is a cross-sectional view showing a Zener diode according to the first embodiment.

FIG. 5 is a plan view showing a Zener diode according to the second embodiment.

FIG. 6 is a plan view showing a Zener diode according to the first modified example.

FIG. 7 is a plan view showing a Zener diode according to the third embodiment.

FIG. 8 is a cross-sectional view showing a Zener diode according to the third embodiment.

FIG. 9 is a plan view showing a Zener diode according to the second modified example.

FIG. 10 is a plan view showing a Zener diode according to the third modified example.

FIG. 11 is a plan view showing a Zener diode according to the fourth modified example.

FIG. 12 is a plan view showing a Zener diode according to the examined example.

### DETAILED DESCRIPTION

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

Also, the X direction, Y direction, and Z direction described in the present application intersect and are orthogonal to each other. In the present application, the Z direction is described as the vertical direction, depth direction, or thickness direction of a structure. Furthermore, expressions such as "plan view" or "plan view" used in the present application mean viewing the plane constituted by the X direction and Y direction from the Z direction.

### FIRST EMBODIMENT

### <STRUCTURE OF SEMICONDUCTOR DEVICE>

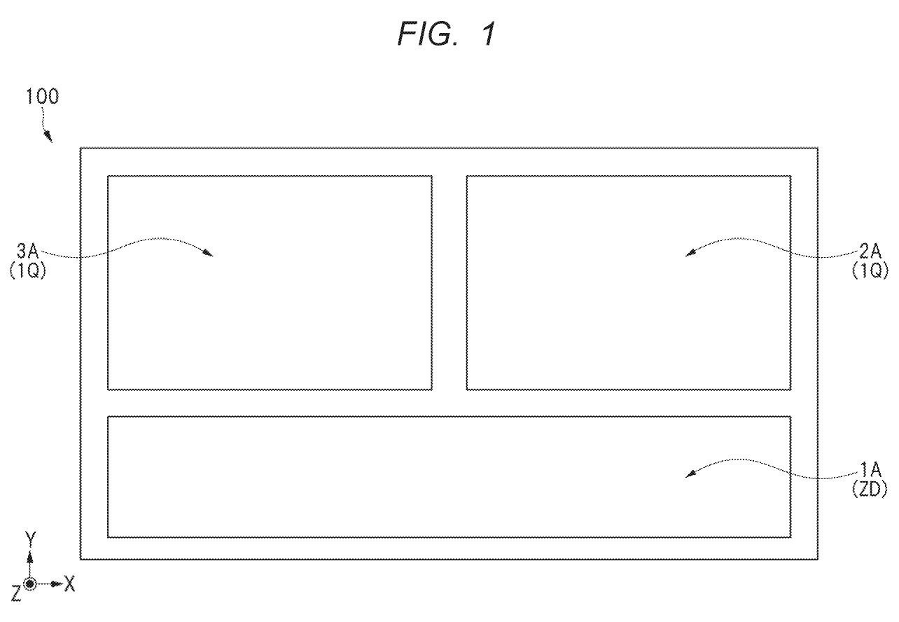

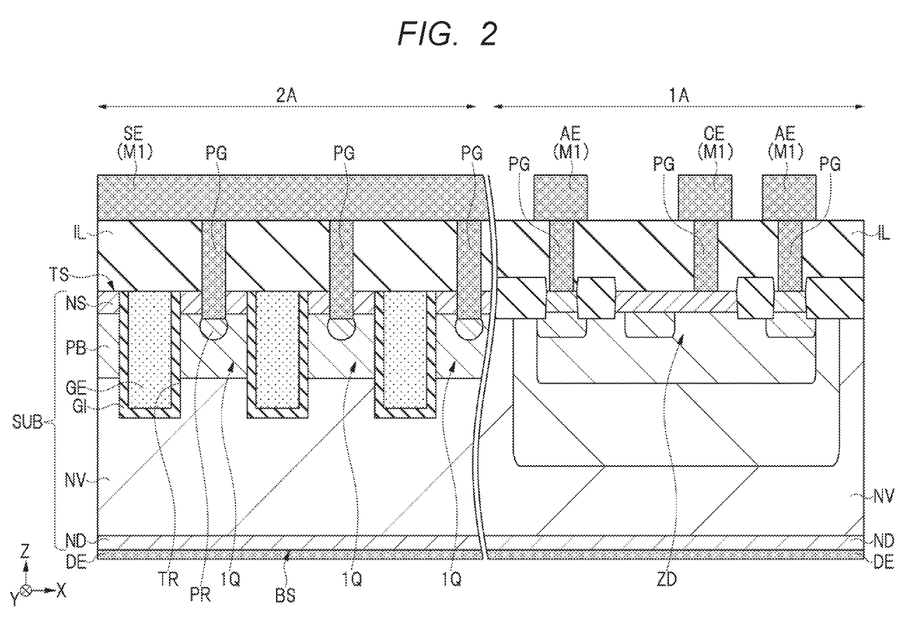

Below, the structure of the semiconductor device (semiconductor chip) 100 in the first embodiment will be described with reference to FIGS. 1 and 2. FIG. 1 shows the planar layout of the semiconductor device 100. FIG. 2 shows the cross-sectional structure of the Zener diode ZD formed in a region 1A and the cross-sectional structure of the power MOSFET 1Q formed in a region 2A.

As shown in FIG. 1, the semiconductor device 100 is an IPD and includes regions 1A, 2A, and 3A. In regions 2A and 3A, multiple n-type power MOSFETs 1Q are formed as output power MOSFETs of the IPD. The power MOSFET 1Q is a trench gate type MOSFET.

Additionally, the semiconductor device 100 includes a control circuit for controlling the operation of each of the multiple power MOSFETs 1Q. The control circuit is formed in the region 1A and includes a gate driver circuit, charge pump circuit, temperature detection circuit, current detection circuit, and protection circuit. As part of these circuits, multiple low breakdown voltage MOSFETs with lower breakdown voltage than the power MOSFETs 1Q are formed in the region 1A. The low breakdown voltage MOSFET is a planar type MOSFET. The protection circuit has the function of protecting multiple low breakdown voltage MOSFETs in the region 1A from surge voltages and the like. In the region 1A, a Zener diode ZD is formed as part of the protection circuit.

The main feature of the present application lies in the structure of the Zener diode ZD. Therefore, hereafter, the Zener diode ZD formed in the region 1A will be exemplified as a representative semiconductor element.

As shown in FIG. 2, the semiconductor device 100 includes an n-type semiconductor substrate SUB having an upper surface TS and a lower surface BS. The semiconductor substrate SUB is made of n-type silicon. The semiconductor substrate SUB has an n-type drift region NV, and an n-type drain region ND.

The semiconductor substrate SUB may be a laminate of an n-type silicon substrate and an n-type silicon layer grown on the silicon substrate by introducing n-type impurities using an epitaxial growth method. In that case, the silicon layer constitutes the drift region NV, and the silicon substrate constitutes the drain region ND.

The impurity concentration of the drain region ND (the silicon substrate) is higher than the impurity concentration of the drift region NV (the silicon layer). That is, the resistivity of the silicon substrate is less than the resistivity of the silicon layer. The resistivity of the silicon layer is equal to or larger than 0.10 Ω·cm, and is equal to or less than 0.20 Ω·cm. Additionally, the thickness of the silicon layer is equal to or larger than 4.0 μm, and is equal to or less than 5.5 μm.

A drain electrode DE is formed on the lower surface BS of the semiconductor substrate SUB. The drain electrode DE consists of a single layer metal film such as an aluminum film, titanium film, nickel film, gold film, or silver film, or a laminated film obtained by appropriately laminating these metal films. The drain electrode DE is formed over the entire lower surface BS of the semiconductor substrate SUB. The drain potential is supplied from the drain electrode DE to the semiconductor substrate SUB (drain region ND, drift region NV).

### <STRUCTURE OF POWER MOSFET 1Q>

Below, the cross-sectional structure of the power MOSFET 1Q in the region 2A will be described with reference to FIG. 2. Note that the cross-sectional structure of the power MOSFET 1Q in a region 3A is the same as the cross-sectional structure of the power MOSFET 1Q in the region 2A.

As shown in FIG. 2, a trench TR is formed in the semiconductor substrate SUB in the region 2A, reaching a predetermined depth from the upper surface TS of the semiconductor substrate SUB. Inside the trench TR, a gate electrode GE is formed via a gate insulating film GI. The gate insulation film GI is, for example, a silicon oxide film. The gate electrode GE is, for example, a polycrystalline silicon film into which n-type impurities are introduced.

In the region 2A, a p-type body region PB is formed in the semiconductor substrate SUB such that a depth of the p-type body region PB from the upper surface TS of the semiconductor substrate SUB is smaller than the depth of the trench TR. An n-type source region NS is formed within the body region PB. The impurity concentration of the source region NS is higher than the impurity concentration of the drift region NV. The portion of the body region PB adjacent to the gate electrode GE via the gate insulating film GI and located between the source region NS and the drift region NV constitutes the channel region of the power MOSFET 1Q.

An interlayer insulating film IL is formed on the upper surface TS of the semiconductor substrate SUB to cover the trench TR. The interlayer insulating film IL is made of, for example, a silicon oxide film. A hole is formed in the interlayer insulating film IL, penetrating the source region NS and reaching the body region PB. At the bottom of the hole, a diffusion region PR is formed within the body region PB. The diffusion region PR has a higher impurity concentration than the body region PB. The diffusion region PR is mainly provided to reduce the contact resistance with the plug PG and to prevent latch-up.

A plug PG is formed inside the hole. The plug PG is electrically connected to the source region NS, body region PB, and diffusion region PR. The plug PG includes, for example, a first barrier metal film and a first conductive film formed on the first barrier metal film. The first barrier metal film is, for example, a laminated film of titanium film and titanium nitride film. The first conductive film is, for example, a tungsten film.

Multiple wirings M1 are formed on the interlayer insulating film IL. The wiring M1 is electrically connected to the plug PG. The wiring M1 includes, for example, a second barrier metal film, a second conductive film formed on the second barrier metal film, and a third barrier metal film formed on the second conductive film. The second barrier metal film and the third barrier metal film are each, for example, laminated films of titanium film and titanium nitride film. The second conductive film is, for example, an aluminum alloy film with added copper or silicon.

In the region 2A, a source electrode SE is formed as the wiring M1. The source potential is supplied from the source electrode SE to the source region NS, body region PB, and diffusion region PR of the power MOSFET 1Q via the plug PG.

Additionally, although not shown, multiple upper layer wirings are formed above the multiple wirings M1. The connection between the control circuit and each gate electrode GE of the multiple power MOSFETs 1Q can be made by routing multiple wirings M1 and multiple upper layer wirings from the region 1A to the region 2A.

### STRUCTURE OF ZENER DIODE ZD

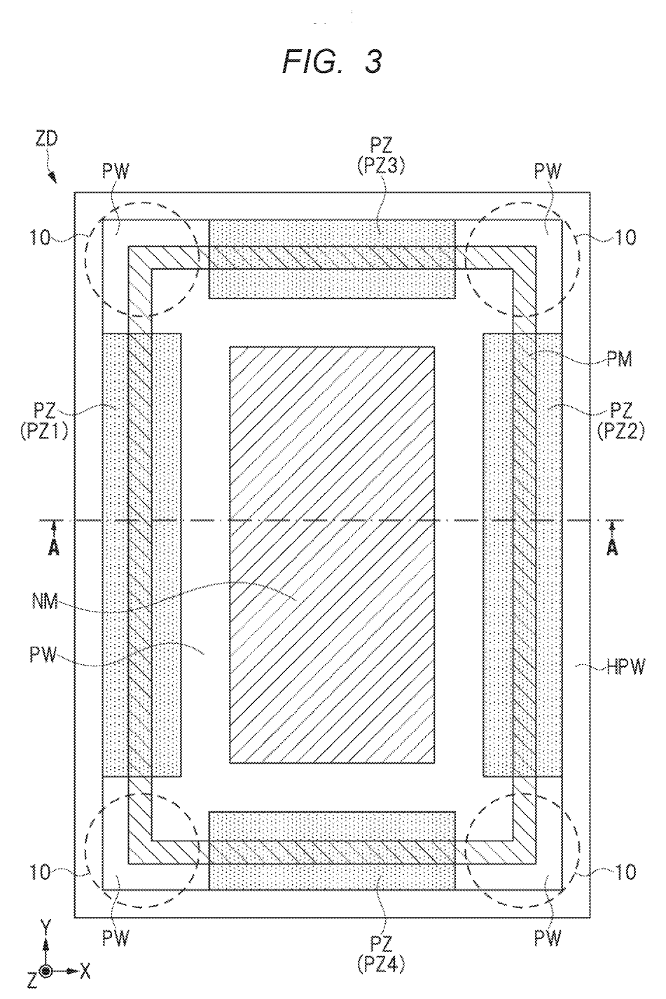

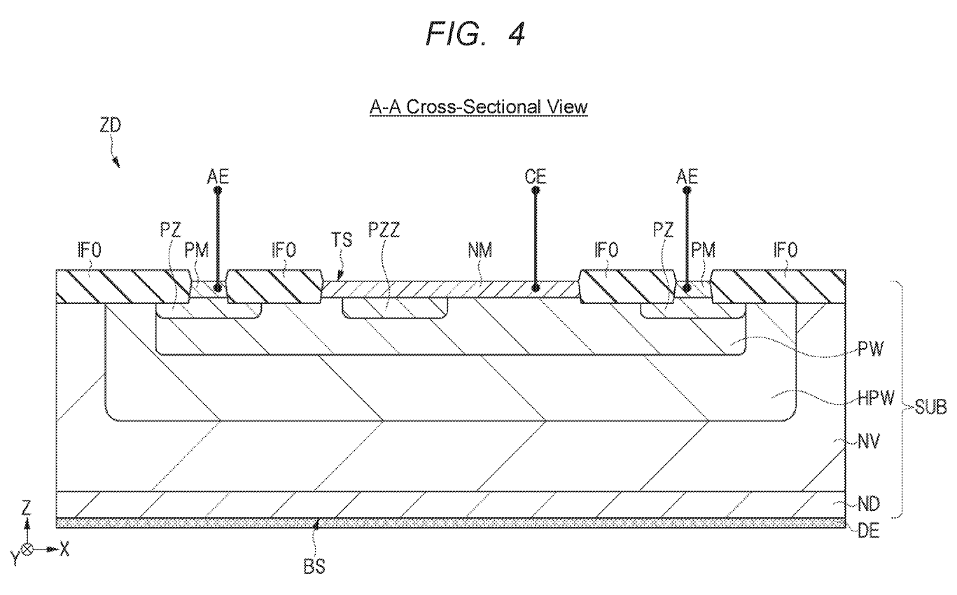

Below, the Zener diode ZD in the region 1A will be described using FIG. 3 and FIG. 4. FIG. 3 shows the planar layout of the Zener diode ZD. FIG. 3 is a cross-sectional view along line A-A shown in FIG. 2.

As shown in FIG. 4, in the region 1A, p-type well region HPW and p-type well region PW are formed in the semiconductor substrate SUB, reaching a predetermined depth from the upper surface TS of the semiconductor substrate SUB. The well region PW is formed within the well region HPW. The well region HPW is mainly provided to increase the breakdown voltage between the p-type anode of the Zener diode ZD and the n-type drift region NV. Therefore, the impurity concentration of the well region HPW is lower than that of the well region PW. In the present embodiment, the impurity concentration of the well region PW is, for example, 5×10^17 cm^-3. Also, the impurity concentration of the well region HPW is, for example, 5×10^16 cm^-3. Furthermore, the well region PW is formed during the process of forming the body region PB. That is, the well region PW is formed at the same timing as the body region PB.

An n-type diffusion region NM is formed within well region PW. The impurity concentration of the diffusion region NM is higher than that of the drift region NV. Additionally, within the well region PW, n-type diffusion region NM, p-type impurity region PZ, and p-type diffusion region PM are formed.

The cathode of the Zener diode ZD includes the diffusion region NM. That is, the diffusion region NM constitutes the cathode of the Zener diode ZD. On the other hand, the anode of the Zener diode ZD includes the diffusion region PM, impurity region PZ, well region PW, and well region HPW. That is, each of the diffusion region PM, impurity region PZ, well region PW, and well region HPW constitutes the anode of the Zener diode ZD. As shown in FIG. 2, above the Zener diode ZD, a cathode electrode CE and an anode electrode AE are formed as wiring M1. The diffusion region NM is electrically connected to the cathode electrode CE via the plug PG. The diffusion region PM is electrically connected to the anode electrode AE via the plug PG.

The impurity region PZ is mainly provided to lower the resistance of the anode of the Zener diode ZD. Therefore, the impurity concentration of the impurity region PZ is higher than that of the well region PW. In the present embodiment, the impurity concentration of the impurity region PZ is, for example, 5×10^18 cm^-3. Note that to lower the resistance of the anode of the Zener diode ZD, the impurity concentration of the well region PW may be increased to the same level as that of the impurity region PZ without forming this impurity region PZ. However, if the impurity concentration of the well region PW is increased to the same level as that of the impurity region PZ, it is necessary to form the well region PW in a different process from the process of forming the body region PB. Furthermore, if the impurity concentration of the well region PW is increased to the same level as that of the impurity region PZ without forming the impurity region PZ, a high concentration impurity region will be formed over a wider area than the low resistance region PZZ (see FIG. 4), including the area directly below the boundary between the diffusion region NM and the field insulating film IF0. As a result, it becomes difficult to control the breakdown voltage.

The impurity concentration of the diffusion region PM is higher than that of the impurity region PZ. The depth of the impurity region PZ from the upper surface TS of the semiconductor substrate SUB is larger than the depth of the diffusion region PM from the upper surface TS of the semiconductor substrate SUB.

By lowering the resistance of the anode of the Zener diode ZD with the impurity region PZ, the amount of current flowing through the Zener diode ZD increases. Therefore, the planar size of the Zener diode ZD can be reduced. That is, if there is no impurity region PZ, the resistance of the anode of the Zener diode ZD increases, and the amount of current flowing through the Zener diode ZD decreases, so measures such as increasing the planar size of the Zener diode ZD are necessary to compensate for the decreased current.

Additionally, to adjust (lower) the Zener voltage of the Zener diode ZD, a p-type low resistance region PZZ may be formed in the area directly below the diffusion region NM within the well region PW. The impurity concentration of the low resistance region PZZ is the same as that of the impurity region PZ and higher than that of the well region PW.

A field insulating film IF0 is formed in the semiconductor substrate SUB. The field insulating film IF0 is, for example, a silicon oxide film. The field insulating film IF0 is formed between the diffusion region NM and the diffusion region PM. Additionally, the field insulating film IF0 is formed on the outer periphery of the diffusion region PM, separating the Zener diode ZD from the low breakdown voltage MOSFET formed in the region 1A.

As shown in FIG. 3, the diffusion region NM is enclosed within well region PW and well region HPW in plan view. The well region PW is enclosed within the well region HPW in plan view. The well region PW and well region HPW form a quadrangular shape in plan view. The diffusion region PM is formed in a ring shape surrounding the diffusion region NM in plan view. More specifically, the diffusion region PM is formed in a square ring shape.

The impurity region PZ surrounds at least a part of the diffusion region NM in plan view. In the first embodiment, the impurity region PZ partially surrounds the diffusion region NM in plan view. The impurity region PZ includes the first portion PZ1 and the second portion PZ2 extending in the Y direction, and the third portion PZ3 and the fourth portion PZ4 extending in the X direction. The diffusion region NM is located between the first portion PZ1 and the second portion PZ2 in the X direction, and between the third portion PZ3 and the fourth portion PZ4 in the Y direction. The diffusion region PM overlaps the first portion PZ1, the second portion PZ2, the third portion PZ3 and the fourth portion PZ4 in plan view.

The first portion PZ1, the second portion PZ2, the third portion PZ3 and the fourth portion PZ4 are physically spaced apart from one another. That is, the first portion PZ1, the second portion PZ2, the third portion PZ3 and the fourth portion PZ4 are not formed at the corner 10 of the Zener diode ZD. Therefore, each corner of the well region PW formed in a quadrangular shape is exposed from the impurity region PZ in a plan view.

It should be noted that corner 10 has corners of the diffusion region PM formed in a square ring shape. In each corner of the diffusion region PM formed in a square ring shape, the portion extending in the Y direction and the portion extending in the X direction intersect and connect with each other.

Additionally, as in other embodiments described later, there may also be corners of the impurity region PZ formed in a square ring shape at corner 10. In each corner of the impurity region PZ formed in a square ring shape, the portion extending in the Y direction and the portion extending in the X direction intersect and connect with each other.

### <MAIN FEATURES OF FIRST EMBODIMENT>

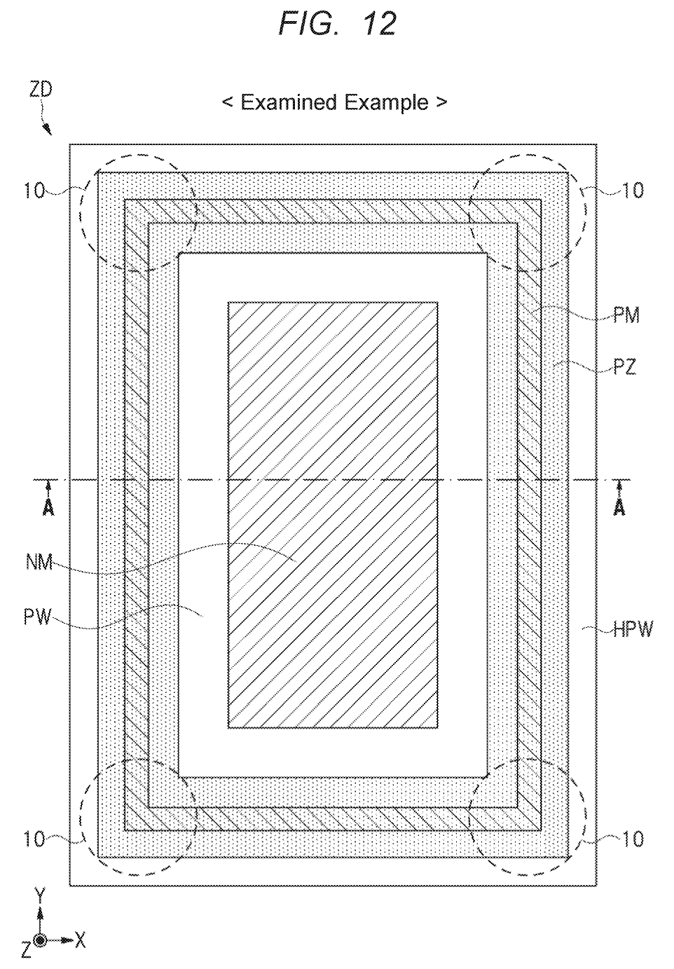

The main features of the first embodiment will be described below, but first, an examined example will be explained. FIG. 12 shows the planar layout of the Zener diode ZD in the examined example studied by the inventors of the present application.

As shown in FIG. 12, in the examined example, the impurity region PZ is formed in a ring shape surrounding the diffusion region NM in a plan view. More specifically, the impurity region PZ is formed in a square ring shape. Therefore, in the examined example, unlike the first embodiment, the impurity region PZ is also formed at corner 10. Each corner of the well region PW formed in a quadrangular shape is not exposed from the impurity region PZ in a plan view.

As mentioned above, in recent years, to reduce the on-resistance of power MOSFET1Q, the thickness of the drift region NV has become thinner, and the impurity concentration of the drift region NV has increased compared to the past. By forming a relatively high concentration impurity region PZ, the current flowing through the Zener diode ZD can be increased, but the electric field generated around the impurity region PZ becomes stronger than the electric field generated directly under the diffusion region NM, for example. That is, it becomes difficult to ensure the breakdown voltage between the p-type anode of the Zener diode ZD and the n-type drift region NV around the impurity region PZ.

Particularly, at corner 10, the electric field generated from the portion of the impurity region PZ extending in the Y direction overlaps with the electric field generated from the portion extending in the X direction. In other words, a relatively strong electric field is concentrated at corner 10. Therefore, in the examined example, there is a problem that it is difficult to ensure the breakdown voltage at corner 10.

In the first embodiment, by separating the impurity region PZ, which has a higher impurity concentration than the well region PW (i.e., a region with a higher impurity concentration than the well region HPW), into the first portion PZ1, the second portion PZ2, the third portion PZ3, and the fourth portion PZ4, the impurity region PZ is not formed at corner 10. Therefore, the amount of current flowing through the Zener diode ZD is greater in the examined example than in the first embodiment. However, in the first embodiment, it is easier to ensure the breakdown voltage at corner 10 compared to the examined example. In other words, in the first embodiment, it is possible to achieve both securing the amount of current flowing through the Zener diode ZD and ensuring the breakdown voltage at corner 10, thereby improving the performance of the semiconductor device 100 and ensuring its reliability.

### (SECOND EMBODIMENT)

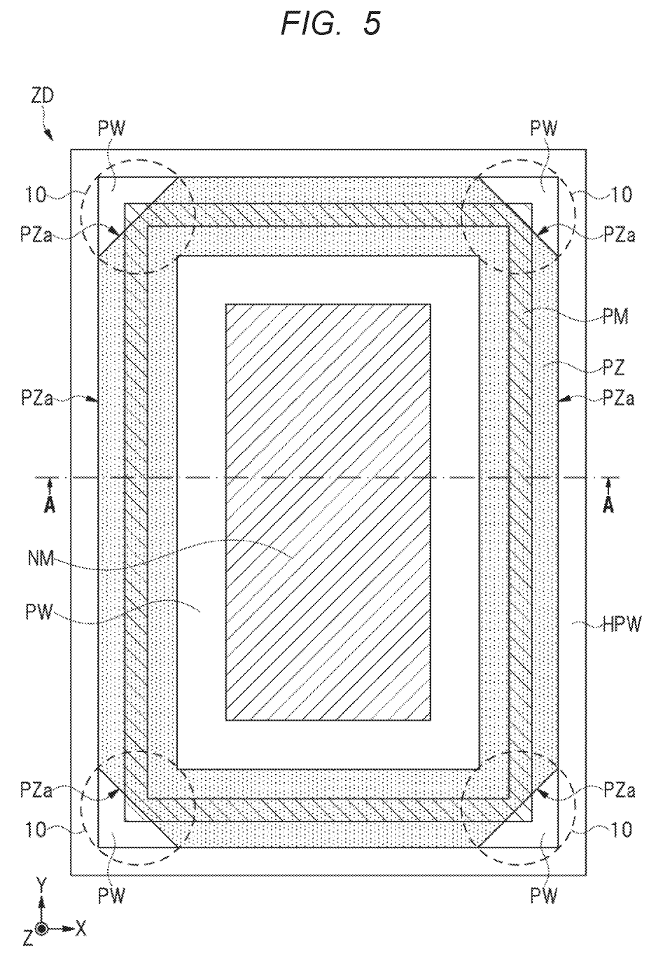

The semiconductor device 100 in the second embodiment will be described below with reference to FIG. 5. In the following description, the differences from the first embodiment will be mainly explained, and the points overlapping with the first embodiment will be omitted.

As shown in FIG. 5, in the second embodiment, the impurity region PZ is formed in a ring shape surrounding the diffusion region NM in a plan view. More specifically, the impurity region PZ is formed in a square ring shape. Therefore, the impurity region PZ has an inner periphery and an outer periphery. In FIG. 5, the outer periphery of the impurity region PZ is shown as outer periphery PZa. The diffusion region PM overlaps the impurity region PZ in a plan view.

Each corner of the well region PW formed in a quadrangular shape is exposed from the impurity region PZ in a plan view. In the second embodiment, the outer periphery PZa of each corner of the impurity region PZ formed in a square ring shape is chamfered.

In other words, the outer periphery PZa of each corner of the impurity region PZ extends in a direction different from the Y and X directions in a plan view.

Therefore, in the second embodiment, compared to the examined example, the concentration of the electric field at corner 10 can be alleviated, making it easier to ensure the breakdown voltage at corner 10. Also, in the second embodiment, since the impurity region PZ is formed at corner 10, compared to the first embodiment, the electric field tends to concentrate at corner 10, but the amount of current flowing through the Zener diode ZD can be increased.

### (FIRST MODIFIED EXAMPLE)

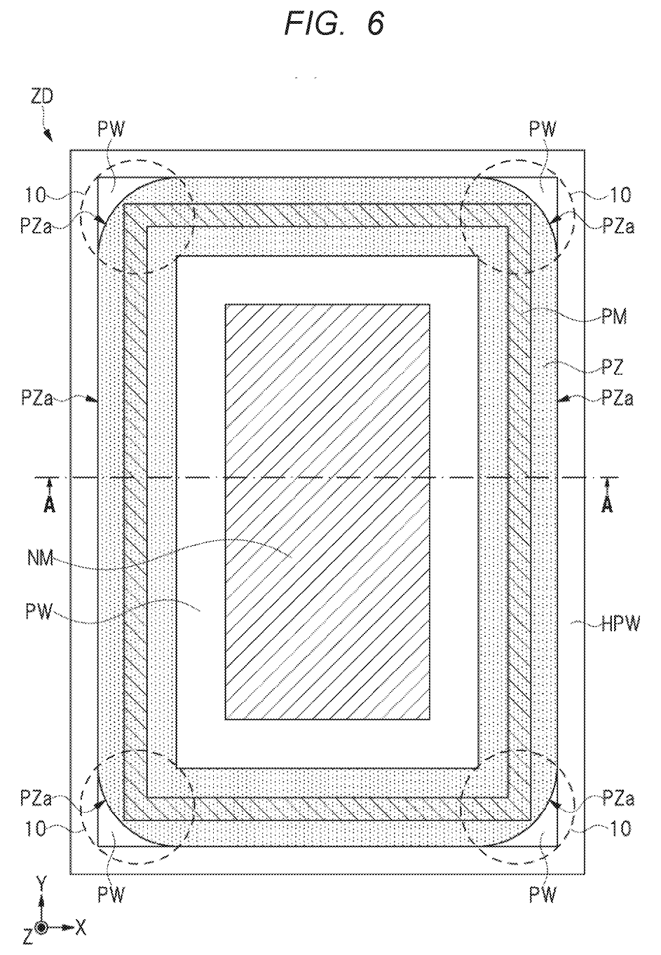

FIG. 6 shows the Zener diode ZD in the first modified example of the second embodiment. As shown in FIG. 6, in the first modified example, similar to the second embodiment, the impurity region PZ is formed in a ring shape so as to surround the diffusion region NM in plan view and is formed in a square ring shape. The diffusion region PM overlaps the impurity region PZ in plan view.

In the first modified example, each corner of the well region PW formed in a quadrangular shape is exposed from the impurity region PZ in a plan view. In the first modified example, the outer periphery PZa of each corner of the impurity region PZ formed in a square ring shape forms a curved shape. Even with such a Zener diode ZD in the first modified example, almost the same effect as the second embodiment can be obtained.

### (THIRD EMBODIMENT)

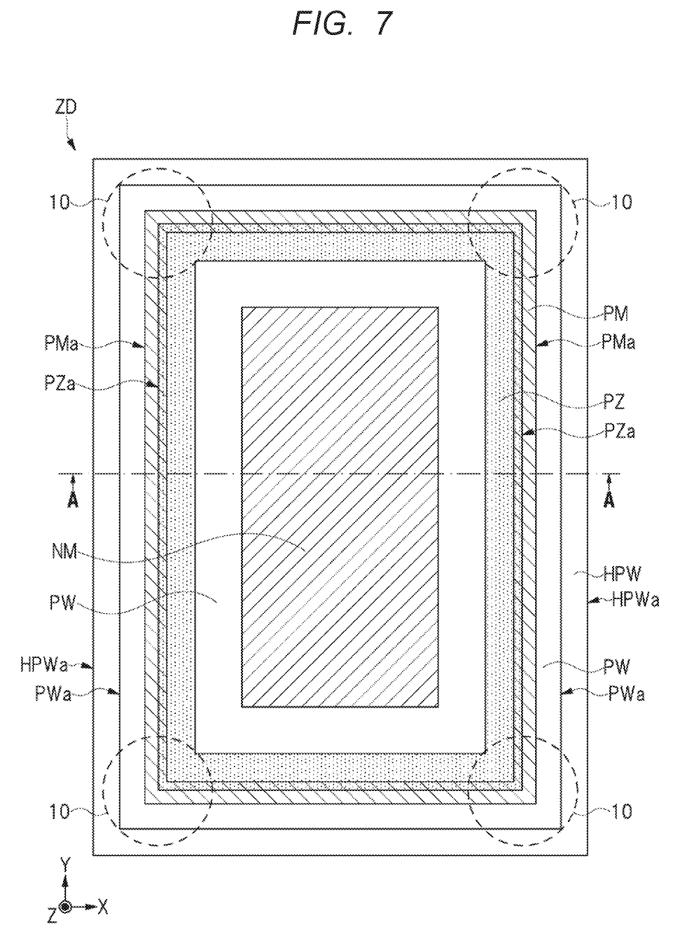

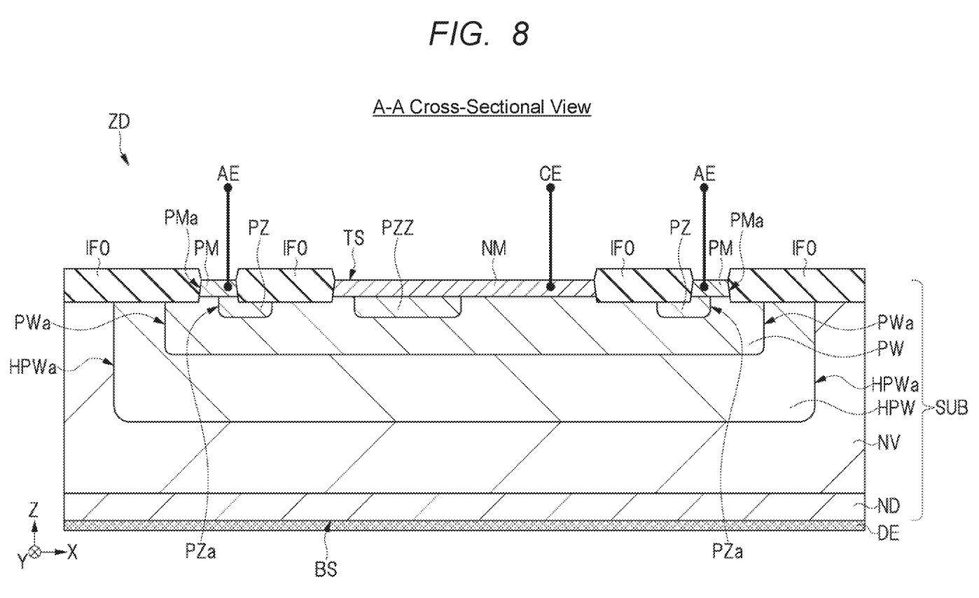

The semiconductor device 100 in the third embodiment will be described below with reference to FIGS. 7 and 8. In the following description, the differences from the first embodiment will be mainly explained, and the points overlapping with the first embodiment will be omitted.

As shown in FIG. 7, in the third embodiment, the impurity region PZ is formed in a ring shape surrounding the diffusion region NM in a plan view. More specifically, the impurity region PZ is formed in a square ring shape. In FIG. 7, the outer periphery of the impurity region PZ is shown as an outer periphery PZa, the outer periphery of the diffusion region PM is shown as an outer periphery PMa, the outer periphery of the well region PW is shown as an outer periphery PWa, and the outer periphery of the well region HPW is shown as an outer periphery HPWa.

The diffusion region PM overlaps with the impurity region PZ in a plan view. However, as shown in FIGS. 7 and 8, the distance from the outer periphery PZa of the impurity region PZ to the diffusion region NM is less than the distance from the outer periphery PMa of the diffusion region PM to the diffusion region NM. In other words, the distance between the outer periphery PZa of the impurity region PZ and the outer periphery PWa of the well region PW is larger than the distance between the outer periphery PMa of the diffusion region PM and the outer periphery PWa of the well region PW. Also, the distance between the outer periphery PZa of the impurity region PZ and the outer periphery HPWa of the well region HPW is larger than the distance between the outer periphery PMa of the diffusion region PM and the outer periphery HPWa of the well region HPW.

Furthermore, in the third embodiment, not only are each corner of the well region PW formed in a quadrangular shape exposed from the impurity region PZ in a plan view, but the well region PW is also exposed from the impurity region PZ along the entire outer periphery PZa in plan view.

By distancing the outer periphery PZa of the relatively high concentration impurity region PZ from the outer periphery PWa of the well region PW and the outer periphery HPWa of the well region HPW, the relatively strong electric field generated around the impurity region PZ becomes farther from the drift region NV. Therefore, in the third embodiment, compared to the examined example, it becomes easier to ensure the breakdown voltage between the p-type anode of the Zener diode ZD and the n-type drift region NV. Also, in the third embodiment, compared to the examined example, the concentration of the electric field at corner 10 can be alleviated, making it easier to ensure the breakdown voltage. In other words, in the third embodiment as well, it is possible to achieve both securing the amount of current flowing through the Zener diode ZD and ensuring the breakdown voltage between the p-type anode and the n-type drift region NV.

### (SECOND MODIFIED EXAMPLE)

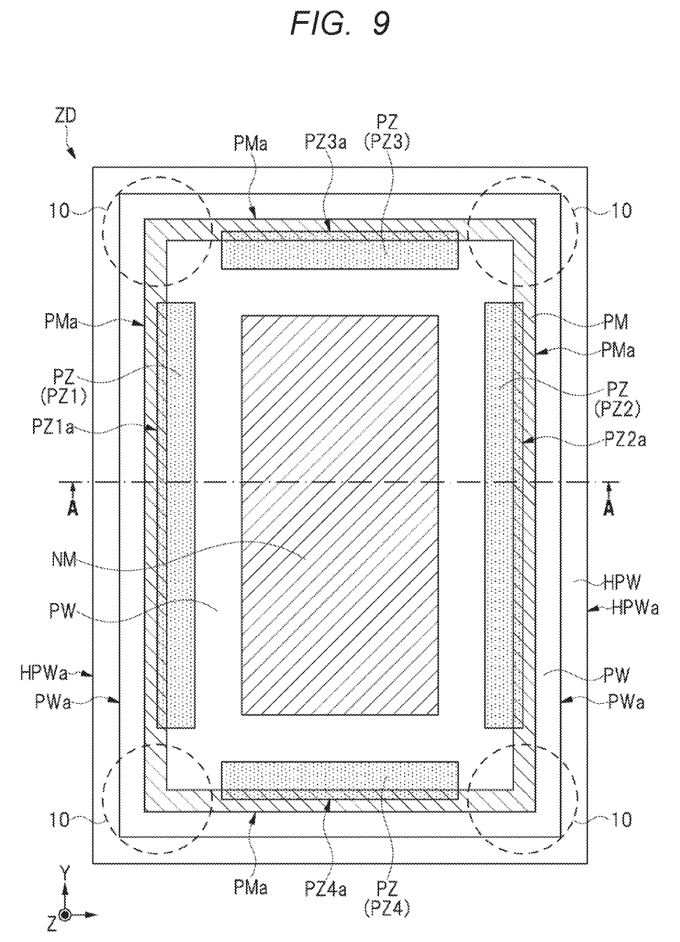

FIG. 9 shows the Zener diode ZD in the second modified example of the third embodiment. In the second modified example, the technology of the third embodiment is applied in combination with the technology of the first embodiment.

As shown in FIG. 9, the first portion PZ1, the second portion PZ2, the third portion PZ3 and the fourth portion PZ4 of the first embodiment are distanced from the outer periphery PWa of the well region PW and the outer periphery HPWa of the well region HPW from the state in FIG. 3. That is, the distance from the outer periphery PZ1a of the first portion PZ1, the outer periphery PZ2a of the second portion PZ2, the outer periphery PZ3a of the third portion PZ3 and the outer periphery PZ4a of the fourth portion PZ4 to the diffusion region NM is less than the distance from the outer periphery PMa of the diffusion region PM to the diffusion region NM.

Regarding the amount of current flowing through the Zener diode ZD, the first embodiment has more than the second modified example. However, in the second modified example, compared to the first embodiment, it becomes easier to ensure the breakdown voltage between the p-type anode and the n-type drift region NV.

### (THIRD MODIFIED EXAMPLE)

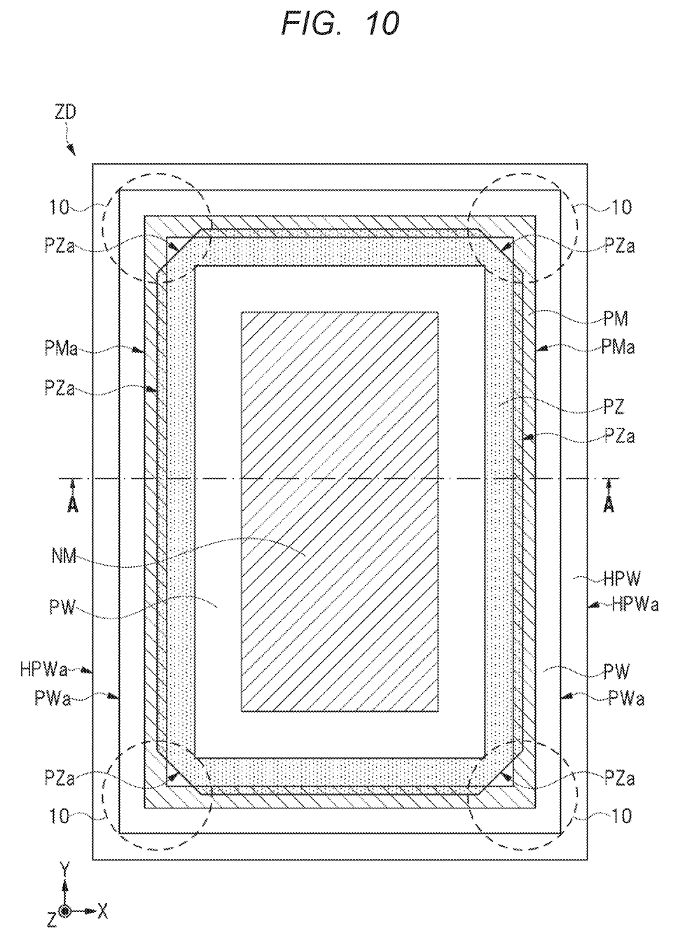

FIG. 10 shows the Zener diode ZD in the third modified example of the second embodiment. In the third modified example, the technology of the third embodiment is applied in combination with the technology of the second embodiment.

As shown in FIG. 10, the impurity region PZ of the second embodiment is distanced from the outer periphery PWa of the well region PW and the outer periphery HPWa of the well region HPW from the state in FIG. 5. That is, the distance from the inner periphery PZa of the impurity region PZ to the diffusion region NM is less than the distance from the outer periphery PMa of the diffusion region PM to the diffusion region NM.

Regarding the amount of current flowing through the Zener diode ZD, the second embodiment has more than the third modified example. However, in the third modified example, compared to the second embodiment, it becomes easier to ensure the breakdown voltage between the p-type anode and the n-type drift region NV.

### (FOURTH MODIFIED EXAMPLE)

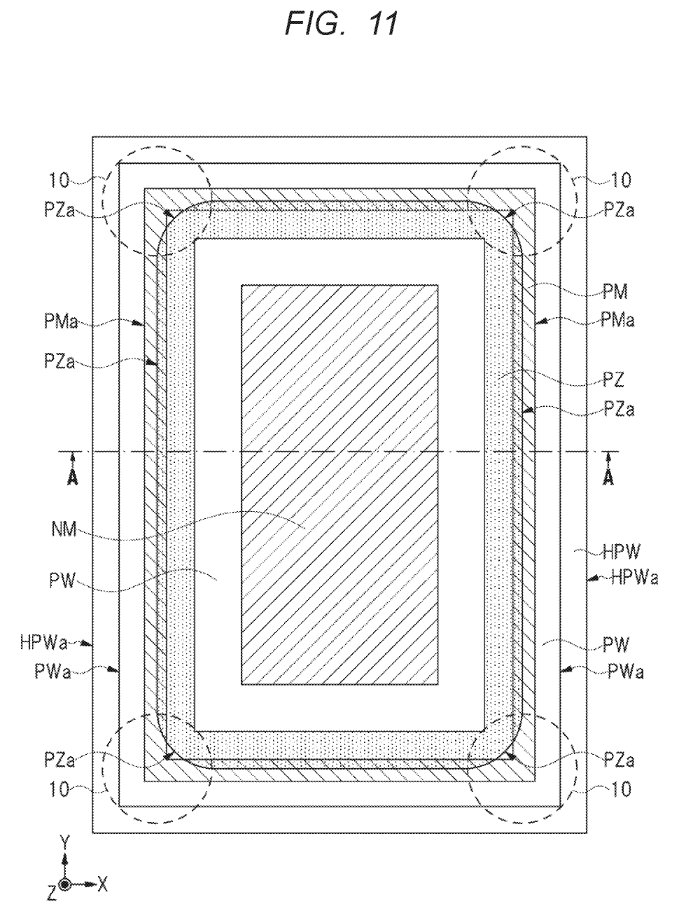

FIG. 11 shows the Zener diode ZD in the fourth modified example of the first modified example. In the fourth modified example, the technology of the third embodiment is applied in combination with the technology of the first modified example.

As shown in FIG. 11, the impurity region PZ of the first modified example is distanced from the outer periphery PWa of the well region PW and the outer periphery HPWa of the well region HPW from the state in FIG. 6. That is, the distance from the inner periphery PZa of the impurity region PZ to the diffusion region NM is less than the distance from the outer periphery PMa of the diffusion region PM to the diffusion region NM.

Regarding the amount of current flowing through the Zener diode ZD, the first modified example has more than the fourth modified example. However, in the fourth modified example, compared to the first modified example, it becomes easier to ensure breakdown voltage between the p-type anode and the n-type drift region NV.

Although the present invention has been specifically described based on the above embodiments, the present invention is not limited to the above embodiments and various modifications can be made without departing from the gist thereof.

What is claimed is:

1. A semiconductor device including a Zener diode, comprising:
a semiconductor substrate having an upper surface and a lower surface, a conductivity type of the semiconductor substrate being an n-type;
a first impurity region formed in the semiconductor substrate so as to reach a predetermined depth from the upper surface of the semiconductor substrate and forming a quadrangular shape in plan view, a conductivity type of the first impurity region being a p-type;
a second impurity region formed in the first impurity region, a conductivity type of the second impurity region being the n-type; and
a third impurity region formed in the first impurity region and surrounding at least a part of the second impurity region in plan view, a conductivity type of the third impurity region being the p-type,
wherein an impurity concentration of the third impurity region is higher than an impurity concentration of the first impurity region,
wherein each corner of the first impurity region is exposed from the third impurity region in plan view,
wherein a cathode of the Zener diode includes the second impurity region, and
wherein an anode of the Zener diode includes the first impurity region and the third impurity region.

2. The semiconductor device according to claim 1,
wherein the third impurity region includes:
a first portion extending in a first direction in plan view;
a second portion extending in the first direction in plan view;
a third portion extending in a second direction orthogonal to the first direction in plan view; and
a fourth portion extending in the second direction in plan view,
wherein the second impurity region is located between the first portion and the second portion in the second direction, and located between the third portion and the fourth portion in the first direction, and
wherein the first portion, the second portion, the third portion and the fourth portion are physically spaced apart from one another.

3. The semiconductor device according to claim 2, further comprising:
a fourth impurity region formed in the first impurity region and formed in a square ring shape so as to surround the second impurity region in plan view, a conductivity type of the fourth impurity region being the p-type,
wherein an impurity concentration of the fourth impurity region is higher than the impurity concentration of the third impurity region,
wherein a depth of the third impurity region from the upper surface of the semiconductor substrate is larger than a depth of the fourth impurity region from the upper surface of the semiconductor substrate,
wherein the fourth impurity region overlaps the first portion, the second portion, the third portion and the fourth portion in plan view, and
wherein the anode of the Zener diode further includes the fourth impurity region.

4. The semiconductor device according to claim 3, wherein a distance from an outer periphery of each of the first portion, the second portion, the third portion and the fourth portion to the second impurity region is less than a distance from an outer periphery of the fourth impurity region to the second impurity region.

5. The semiconductor device according to claim 1,
wherein the third impurity region is formed in a square ring shape so as to surround the second impurity region in plan view,
wherein the impurity concentration of the third impurity region is higher than the impurity concentration of the first impurity region, and
wherein an outer periphery of each corner of the third impurity region is chamfered or forms a curve.

6. The semiconductor device according to claim 5, further comprising:
a fourth impurity region formed in the first impurity region and formed in a square ring shape so as to surround the second impurity region in plan view, a conductivity type of the fourth impurity region being the p-type,
wherein an impurity concentration of the fourth impurity region is higher than the impurity concentration of the third impurity region,
wherein a depth of the third impurity region from the upper surface of the semiconductor substrate is larger than a depth of the fourth impurity region from the upper surface of the semiconductor substrate,
wherein the fourth impurity region overlaps the third impurity region in plan view, and
wherein the anode of the Zener diode further includes the fourth impurity region.

7. The semiconductor device according to claim 6, wherein a distance from an inner periphery of the third impurity region to the second impurity region is less than a distance from an outer periphery of the fourth impurity region to the second impurity region.

8. The semiconductor device according to claim 1, further comprising:
a fourth impurity region formed in the first impurity region and formed in a square ring shape so as to surround the second impurity region in plan view, a conductivity type of the fourth impurity region being the p-type,
wherein the third impurity region is formed in a square ring shape so as to surround the second impurity region in plan view,
wherein the impurity concentration of the third impurity region is higher than the impurity concentration of the first impurity region, and lower than an impurity concentration of the fourth impurity region,
wherein a depth of the third impurity region from the upper surface of the semiconductor substrate is larger than a depth of the fourth impurity region from the upper surface of the semiconductor substrate,
wherein a distance from an inner periphery of the third impurity region to the second impurity region is less than a distance from an outer periphery of the fourth impurity region to the second impurity region, and
wherein the anode of the Zener diode further includes the fourth impurity region.

9. The semiconductor device according to claim 8, wherein the fourth impurity region overlaps the third impurity region in plan view.

10. The semiconductor device according to claim 1, further comprising:
a fifth impurity region formed in the semiconductor substrate such that a depth of the fifth impurity region from the upper surface of the semiconductor substrate is larger than the predetermined depth of the first impurity region, a conductivity type of the fifth impurity region being the p-type,
wherein the first impurity region is formed in the fifth impurity region and is enclosed within the fifth impurity region in plan view, and
wherein the anode of the Zener diode further includes the fifth impurity region.

11. The semiconductor device according to claim 1,
wherein the semiconductor substrate includes a silicon substrate and a silicon layer formed on the silicon substrate, a conductivity type of each of the silicon substrate and the silicon layer being the n-type,
wherein a resistivity of the silicon substrate is less than a resistivity of the silicon layer,
wherein the resistivity of the silicon layer is equal to or larger than 0.10 Ω·cm, and is equal to or less than 0.20 Ω·cm, and
wherein the thickness of the silicon layer is equal to or larger than 4.0 μm, and is equal to or less than 5.5 μm.

12. The semiconductor device according to claim 1, further comprising:
a first region in which the Zener diode is formed;
a second region in which a power MOSFET is formed; and
a drain electrode formed on the lower surface of the semiconductor substrate,
wherein the power MOSFET has:
a trench formed in the semiconductor substrate so as to reach a predetermined depth from the upper surface of the semiconductor substrate in the second region;
a gate electrode formed inside the trench via a gate insulating film;
a body region formed in the semiconductor substrate in the second region such that a depth of the body region from the upper surface of the semiconductor substrate is smaller than a depth of the trench; and
a source region formed in the body region, a conductivity type of the source region being the n-type.
